(19) United States
(12) Patent Application Publication
(10) Pub. No.: US 2016/0274706 A1
(43) Pub. Date: Sep. 22, 2016

(54) TOUCH SENSOR FOR CURVED DISPLAY AND METHOD FOR MANUFACTURING THE SAME

(71) Applicants: Hyundai Motor Company, Seoul (KR); IM Co., Ltd., Hwaseong (KR)

(72) Inventors: Kyoung Chun Kweon, Seoul (KR); Ji Hun Park, Seoul (KR); Seong Hwan Lim, Seoul (KR); Eui Joong Kim, Suwon (KR); Ho Seop Song, Seoul (KR)

(21) Appl. No.: 14/752,967

(22) Filed: Jun. 28, 2015

(30) Foreign Application Priority Data
Mar. 20, 2015 (KR) 10-2015-0039160

(51) Int. Cl. G06F 3/041; G06F 1/16; C23C 16/06; G06F 3/044

(52) U.S. Cl. CPC G06F 3/0412; G06F 3/044; G06F 1/1652; C23C 16/06; G06F 2203/04103; G06F 2203/04102

(57) ABSTRACT

A touch sensor for a curved display includes: a first sensor including a) first sensor patterns arranged on a first flexible plastic substrate so as to be continuous in a first direction and spaced apart from each other by a predetermined interval in a second direction and b) first dummy patterns arranged between the first sensor patterns on the first flexible plastic substrate; a second sensor including a) second sensor patterns arranged on a second flexible plastic substrate so as to be continuous in the second direction and be spaced apart from each other by a predetermined interval in the first direction and b) second dummy patterns arranged between the second sensor patterns on the second flexible plastic substrate; and an adhering part causing the first sensor and the second sensor to adhere to each other.

### CROSS-REFERENCE TO RELATED APPLICATION

This application claims the benefit of and priority to Korean Patent Application No. 10-2015-0039160, filed on Mar. 20, 2015 in the Korean Intellectual Property Office, the disclosure of which is incorporated herein in its entirety by reference.

### TECHNICAL FIELD

The present disclosure relates generally to a touch sensor for a display, and more particularly, to a touch sensor capable of having improved visibility and being used for a curved display, and a method for manufacturing the same.

### BACKGROUND

Recently, touch panels have been used as input devices in electronic apparatuses such as a mobile phone, a navigation device, an automatic teller machine, and the like. The touch panel is typically divided into layers, including a resistive type touch panel, a capacitive type touch panel, an infrared type touch panel, an ultrasonic type touch panel, and the like, depending on a structure thereof. Among them, the resistive type touch panel and the capacitive type touch panel have been primarily used in recent development.

The resistive type touch panel has a structure in which two substrates each having a transparent conductive layer formed thereon are disposed so as to be spaced apart from each other by a predetermined interval, and is operated in a scheme in which it recognizes an input coordinate by a resistance value changed by a contact between the transparent conductive layers at the time of touching the resistive type touch panel. Since the resistive type touch panel as described above has a narrow operating range, implementing multi-touch functionality can be difficult. Further, the panel has a structure in which the two substrates are disposed so as to be spaced apart from each other, and thus, suffers from a problem in that optical characteristics such as luminance, contrast, and the like, become deficient.

On the other hand, the capacitive type touch panel is manufactured by forming transparent conductive layers on one or two substrates and etching the transparent conductive layers in a predetermined pattern shape in order to recognize a touch to form a channel region in which electricity flows and a non-channel region in which the electricity does not flow. The capacitive type touch panel as described above is operated in a scheme in which it recognizes an input coordinate by sensing that capacitances have changed in the respective channels in which patterns are formed when it is touched by a finger, or the like. This panel has an advantage in that it may be formed to be thinner than that of the resistive type touch panel, and it may implement multi-touch functionality.

As is known in the art, a material of an electrode used in the touch panel should be transparent and have a low sheet resistance. For instance, indium tin oxide (ITO) has been mainly used as a transparent electrode in existing touch panels. The reason for usage of ITO is that ITO is a material with high transmissivity (>85%) and low sheet resistance (<200Ω). However, since indium, which is a main raw material of the ITO and a rare metal, is expensive and requires a high temperature sputtering technology, the process cost is high. Further, ITO has poor flexibility, such that the material is limited in touch panel applications, such as a large-area display and a flexible display.

In addition, a metal mesh type technology using a conductive polymer and a silver powder as a substitute material for overcoming the above limitations limitation has been developed. However, the conductive polymer and the silver powder are easily oxidized in the air and have low heat resistance, such that effective use of the conductive polymer and the silver powder is limited. Particularly, the conductive polymer has a phenomenon that ink is lumped or spread after being printed, and the metal mesh is oxidized, such that the metal mesh has visibility poor enough to be distinguished with the naked eye.

### SUMMARY

The present disclosure has been made to solve the above-mentioned problems occurring in the related art while advantages achieved by the prior art are maintained intact.

An aspect of the present disclosure provides a touch sensor capable of having improved visibility, having a simple process, and being used for a curved display.

According to embodiments of the present disclosure, a touch sensor for a curved display includes: a first sensor including a) first sensor patterns arranged on a first flexible plastic substrate so as to be continuous in a first direction and spaced apart from each other by a predetermined interval in a second direction and b) first dummy patterns arranged between the first sensor patterns on the first flexible plastic substrate; a second sensor including a) second sensor patterns arranged on a second flexible plastic substrate so as to be continuous in the second direction and be spaced apart from each other by a predetermined interval in the first direction and b) second dummy patterns arranged between the second sensor patterns on the second flexible plastic substrate; and an adhering part causing the first sensor and the second sensor to adhere to each other.

The first flexible plastic substrate or the second flexible plastic substrate may contain polyethylene terephthalate (PET).

The first sensor patterns may be formed in a form in which hexagonal electrode patterns are continuously connected to each other in the first direction.

The second sensor patterns may be formed in a form in which hexagonal electrode patterns are continuously connected to each other in the second direction.

The first dummy patterns may include: main dummy patterns including octagonal electrode patterns disposed between the first sensor patterns so as to be spaced apart from each other by a predetermined interval; and auxiliary dummy patterns including rectangular electrode patterns disposed between the main dummy patterns.

The first and second sensor patterns may contain a fluorine-doped tin oxide (FTO).

The first and second dummy patterns may contain a fluorine-doped tin oxide (FTO)

Furthermore, according to embodiments of the present disclosure, a method for manufacturing a touch sensor for a curved display includes: forming photoresist patterns defining electrode pattern regions and dummy pattern regions on a flexible plastic substrate; forming electrode patterns on the flexible plastic substrate between the photoresist patterns; and removing the photoresist patterns after the electrode patterns are formed on the flexible plastic substrate.

The forming of the electrode patterns may include depositing a fluorine-doped tin oxide (FTO) on a polyethylene terephthalate (PET) substrate.

The depositing of the FTO on the PET substrate may include depositing the FTO on the PET substrate using electron-cyclotron-resonance (ECR)-metal organic chemical vapor deposition (MOCVD).

Objects of the present disclosure are not limited to the above-mentioned objects. That is, other objects that are not mentioned may be obviously understood by those skilled in the art.

### BRIEF DESCRIPTION OF THE DRAWINGS

The above and other objects, features and advantages of the present disclosure will be more apparent from the following detailed description taken in conjunction with the accompanying drawings.

FIG. 1 is an exploded view illustrating a structure of each layer of a touch sensor according to embodiments of the present disclosure.

FIG. 2 is a cross-sectional view taken along line A-A′ of FIG. 1.

FIG. 3 is a view illustrating a form in which sensor patterns of a first sensor and sensor patterns of a second sensor in the touch sensor of FIG. 1 are formed so as to intersect with each other.

FIG. 4 is a partially enlarged view of the first sensor in FIG. 1.

FIGS. 5A to 5D are views illustrating a process sequence for describing a direct deposition scheme according to embodiments of the present disclosure.

### DETAILED DESCRIPTION OF THE EMBODIMENTS

Hereinafter, embodiments of the present disclosure will be described with reference to the accompanying drawings. It is to be noted that in giving reference numerals to components of the accompanying drawings, the same components will be denoted by the same reference numerals even though they are illustrated in different drawings. Further, in describing embodiments of the present disclosure, well-known constructions or functions will not be described in detail in the case in which it is decided that they may unnecessarily obscure the understanding of the present disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

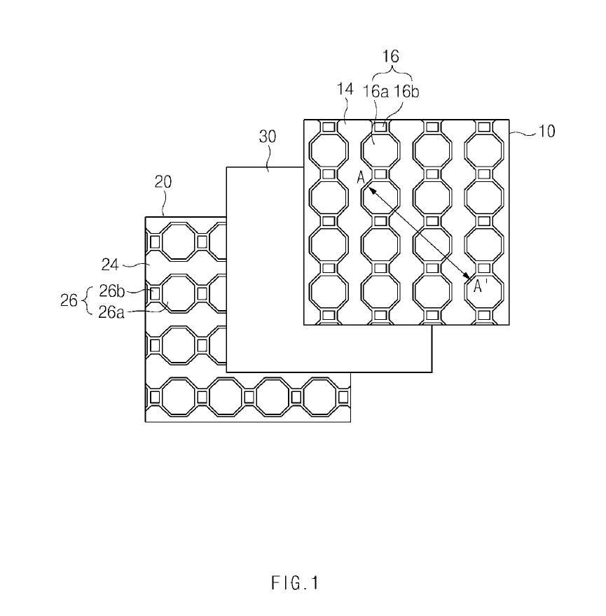

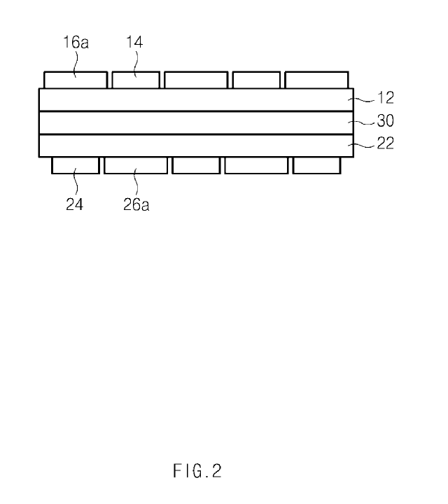

Referring now to the disclosed embodiments, FIG. 1 is an exploded view illustrating a structure of each layer of a touch sensor according to embodiments of the present disclosure, and FIG. 2 is a cross-sectional view taken along line A-A′ of FIG. 1.

The touch sensor according to the presently disclosed embodiments is configured to include a first sensor 10, a second sensor 20, and an adhering part 30.

The first sensor 10 includes sensor patterns 14 and dummy patterns 16 formed on a substrate 12. The substrate 12 contains polyethylene terephthalate (PET), which is a flexible plastic material. The sensor patterns 14 are formed on the substrate 12 so as to be continuously connected to each other in a line type in a first direction (e.g., Y-axis direction) and are disposed so as to be spaced apart from each other by a predetermined interval in a second direction (e.g., X-axis direction). The sensor patterns 14 may be formed in a form in which hexagonal electrode patterns are continuously connected to each other in the first direction. The dummy patterns 16 are positioned between the sensor patterns 14, and each include a main dummy pattern 16a and an auxiliary dummy pattern 16b that are not electrically connected to each other. The main dummy patterns 16a include octagonal electrode patterns disposed so as to be spaced apart from each other by a predetermined interval in the first direction, and the auxiliary dummy patterns 16b include rectangular electrode patterns disposed between the main dummy patterns 16a in the first direction. The sensor patterns 14 and the dummy patterns 16 contain a high-density fluorine-doped tin oxide (FTO).

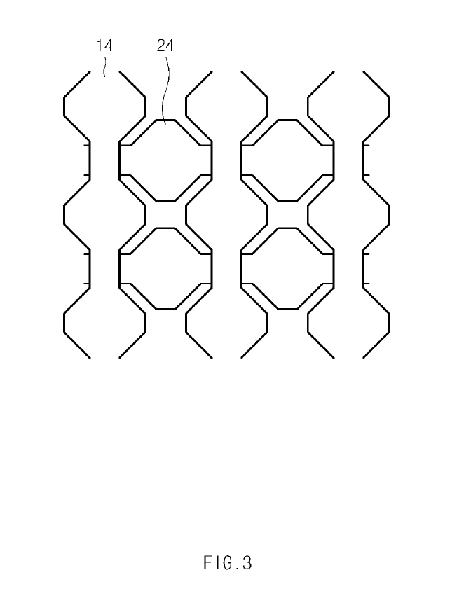

The second sensor 20 includes sensor patterns 24 and dummy patterns 26 formed on a substrate 22. The substrate 22 contains polyethylene terephthalate (PET), which is a flexible plastic material. The sensor patterns 24 are formed on the substrate 22 so as to be continuously connected to each other in a line type in the second direction (e.g., X-axis direction) and are disposed so as to be spaced apart from each other by a predetermined interval in the first direction (e.g., Y-axis direction). That is, the sensor patterns 14 of the first sensor 10 and the sensor patterns 24 of the second sensor 20 are formed so as to intersect with each other, as illustrated in FIG. 3. The sensor patterns 24 may be formed in a form in which hexagonal electrode patterns are continuously connected to each other in the second direction. The dummy patterns 26 are positioned between the sensor patterns 24, and each include a main dummy pattern 26a and an auxiliary dummy pattern 26b that are not electrically connected to each other. The main dummy patterns 26a include octagonal electrode patterns disposed so as to be spaced apart from each other by a predetermined interval in the first direction, and the auxiliary dummy patterns 26b include rectangular electrode patterns disposed between the main dummy patterns 26a in the first direction. The sensor patterns 24 and the dummy patterns 26 contain a high-density fluorine-doped tin oxide (FTO).

The adhering part 30 is formed between the first sensor 10 and the second sensor 20 to cause the first sensor 10 and the second sensor 20 to adhere to each other. The adhering part 30 includes an optically clear adhesive (OCA).

As described above, in the touch sensor according to the present disclosure, the sensor patterns and the dummy patterns are formed in a form in which the high-density fluorine-doped tin oxide (FTO) is deposited on the substrate made of the flexible plastic material (PET). The fluorine-doped tin oxide (FTO) patterns are formed on the substrate made of the PET using an electron-cyclotron-resonance (ECR) plasma method.

For example, the sensor patterns 14 and 24 and the dummy patterns 16a, 16b, 26a, and 26b are formed by making an inner portion of an ECR-metal organic chemical vapor deposition (MOCVD) chamber an FTO gas atmosphere at room temperature (about 80° C.) and then passing a PET film through the ECR-MOCVD chamber by a roll-to-roll process to allow an FTO layer to be deposited on the PET film. Here, the sensor patterns and the dummy patterns may be formed in a direct deposition scheme. The direct deposition scheme will be described below.

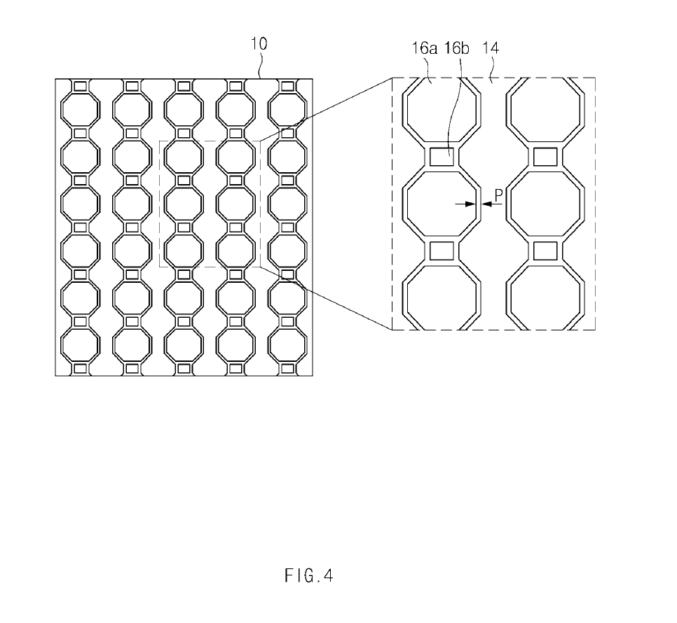

FIG. 4 is a partially enlarged view of the first sensor 10 in FIG. 1.

In the disclosed embodiments, the sensor patterns 14 are designed as hexagonal patterns, and the dummy patterns 16a between the sensor patterns are formed in an octagonal pattern form, such that intervals P between the sensor pattern 14 and the dummy pattern 16a may be finely formed to be about 0.5 μm. Therefore, it is possible to improve visibility and lower a sheet resistance as compared with sensor patterns having a diamond structure according to the related art.

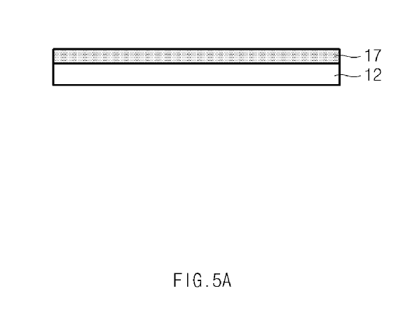

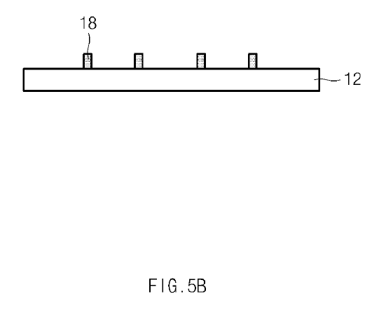

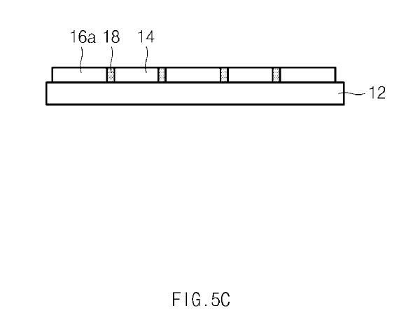

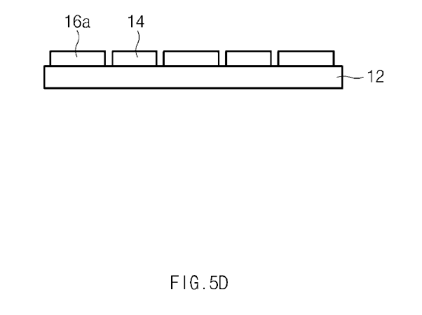

FIGS. 5A to 5D are views illustrating a process sequence for describing a direct deposition scheme according to embodiments of the present disclosure. Hereinafter, only a process for forming the first sensor will be described by way of example for convenience of explanation.

First, as shown in FIG. 5A, a photoresist layer 17 is formed on a PET film 12.

Next, as shown in FIG. 5B, exposure and development processes are performed on the photoresist layer 17 using a mask (i.e., reticle) defining electrode pattern and dummy pattern regions to form photoresist patterns 18 defining the electrode pattern and dummy pattern regions.

That is, the photoresist patterns 18 defining the electrode pattern and dummy pattern regions are formed by allowing the photoresist layer to remain only in regions in which the sensor patterns 14 and the dummy patterns 16a and 16b are not formed in FIG. 1 (i.e., regions between the sensor patterns 14 and the dummy patterns 16a and 16b and regions between the dummy patterns 16a and 16b).

Next, as shown in FIG. 5C, the FTO is deposited on the PET film 12 using the above-mentioned electron-cyclotron-resonance (ECR) plasma method to form the FTO layer in regions between the photoresist patterns 18, that is, regions in which the sensor patterns 14 and the dummy patterns 16a and 16b are formed in FIG. 1.

Next, as shown in FIG. 5D, only the photoresist patterns are selectively removed using etch selectivity of the photoresist patterns 18 and the FTO layer to form the sensor patterns 14 and the dummy patterns 16a, 16b, 26a, and 26b on the PET film 12, as illustrated in FIG. 1.

The spirit of the present disclosure has been illustratively described hereinabove. It will be appreciated by those skilled in the art that various modifications and alterations may be made without departing from the essential characteristics of the present disclosure.

As described above, according to embodiments of the present disclosure, the visibility of the touch sensor may be improved, and a process may be simplified to decrease a production cost. In addition, the sensor patterns are formed using a flexible tin oxide, such that the touch sensor may be used for the curved display.

Accordingly, embodiments disclosed in the present disclosure are not to limit the spirit of the present disclosure, but are to describe the spirit of the present disclosure. That is, the scope of the present disclosure is not limited to these embodiments. Instead, the scope of the present disclosure should be interpreted by the following claims, and it should be interpreted that all the spirits equivalent to the following claims fall within the scope of the present disclosure.

What is claimed is:

1. A touch sensor for a curved display, comprising:
a first sensor including a) first sensor patterns arranged on a first flexible plastic substrate so as to be continuous in a first direction and spaced apart from each other by a predetermined interval in a second direction and b) first dummy patterns arranged between the first sensor patterns on the first flexible plastic substrate;
a second sensor including a) second sensor patterns arranged on a second flexible plastic substrate so as to be continuous in the second direction and be spaced apart from each other by a predetermined interval in the first direction and b) second dummy patterns arranged between the second sensor patterns on the second flexible plastic substrate; and
an adhering part causing the first sensor and the second sensor to adhere to each other.

2. The touch sensor for a curved display according to claim 1, wherein the first flexible plastic substrate or the second flexible plastic substrate contains polyethylene terephthalate (PET).

3. The touch sensor for a curved display according to claim 2, wherein the first sensor patterns are formed in a form in which hexagonal electrode patterns are continuously connected to each other in the first direction.

4. The touch sensor for a curved display according to claim 3, wherein the second sensor patterns are formed in a form in which hexagonal electrode patterns are continuously connected to each other in the second direction.

5. The touch sensor for a curved display according to claim 4, wherein the first dummy patterns include:
main dummy patterns including octagonal electrode patterns disposed between the first sensor patterns so as to be spaced apart from each other by a predetermined interval; and
auxiliary dummy patterns including rectangular electrode patterns disposed between the main dummy patterns.

6. The touch sensor for a curved display according to claim 2, wherein the first and second sensor patterns contain a fluorine-doped tin oxide (FTO).

7. The touch sensor for a curved display according to claim 2, wherein the first and second dummy patterns contain a fluorine-doped tin oxide (FTO).

8. A method for manufacturing a touch sensor for a curved display, comprising:
forming photoresist patterns defining electrode pattern regions and dummy pattern regions on a flexible plastic substrate;
forming electrode patterns on the flexible plastic substrate between the photoresist patterns; and
removing the photoresist patterns after the electrode patterns are formed on the flexible plastic substrate.

9. The method for manufacturing a touch sensor for a curved display according to claim 8, wherein the forming of the electrode patterns comprises:
depositing a fluorine-doped tin oxide (FTO) on a polyethylene terephthalate (PET) substrate.

10. The method for manufacturing a touch sensor for a curved display according to claim 9, wherein the depositing of the FTO on the PET substrate comprises:
depositing the FTO on the PET substrate using electron-cyclotron-resonance (ECR)-metal organic chemical vapor deposition (MOCVD).
